(19) United States
(12) Patent Application Publication
(10) Pub. No.: US 2008/0299499 A1
(43) Pub. Date: Dec. 4, 2008

(54) EXPOSURE METHOD, METHOD OF MANUFACTURING PLATE FOR FLAT PANEL DISPLAY, AND EXPOSURE APPARATUS

(76) Inventor: Naomasa Shiraishi, Saitama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/110,008

(22) Filed: Apr. 25, 2008

Related U.S. Application Data
(60) Provisional application No. 60/924,737, filed on May 30, 2007.

(51) Int. Cl. G03F 7/20; G03B 27/42

(52) U.S. Cl. 430/322; 355/53

(57) ABSTRACT

An exposure method facilitating the formation of a fine pattern on a plate. The exposure method illuminates a mask with illumination light and exposes a plate using a mask pattern of the mask. The method includes scanning the plate relative to the mask in a scanning direction, which is an in-plane direction of the plate, and exposing the plate while scanning the plate relative to the mask. The exposing of the plate while scanning the plate relative to the mask includes performing fine period exposure with a fine period mask pattern formed in a first region of the mask and middle density exposure with a middle density mask pattern formed in a second region of the mask. The first region and the second region are arranged adjacent to each other in the scanning direction.

### CROSS-REFERENCE TO RELATED APPLICATIONS

This application is based upon and claims the benefit of priorities from U.S. Provisional Application No. 60/924,737 filed on May 30, 2007, the entire contents of which are incorporated herein by reference.

### BACKGROUND OF THE INVENTION

The present invention relates to an exposure method and an exposure apparatus used in a lithography process for manufacturing a plate that forms a display screen of a flat panel display, and a method of manufacturing a plate for a flat panel display with the exposure method or the exposure apparatus.

Processes for manufacturing a plate for a flat panel display, such as a liquid crystal display or a plasma display, normally include a lithography process, in which a fine pattern is formed on the plate by employing a photolithography technique. To form a predetermined pattern on a plate with the photolithography technique, photosensitive film (photoresist) is first formed on the surface of the plate. The plate is then exposed to exposure light for which the light distribution is set in accordance with the shape of the pattern (exposure process) that is to be formed. The plate is then subjected to developing and etching processes.

The exposure process performed during the manufacturing of the plate for a flat panel display mainly employs an exposure method using masks. With such an exposure method, a pattern, which is to be transferred to the plate, is first formed on the plate. The mask is then illuminated with illumination light so that the light distributed through the mask is transferred onto the plate.

### SUMMARY OF THE INVENTION

Due to the enlargement of flat panel displays, in addition to the necessity for enlarging plates forming display screens of flat panel displays, masks used to manufacture the plates must also be enlarged. However, enlargement of a mask increases the cost of a mask. Also, the enlargement of equipment for transporting and storing the mask increases equipment costs. Further, four or five layers of masks are used to form the display screen of a flat panel display. Thus, the cost of masks required for the flat panel display is extremely high. Consequently, the production cost of the flat panel display is high.

It is an object of the present invention to provide an exposure method enabling inexpensive formation of fine patterns on a plate used as a display screen of a flat panel display.

It is another object of the present invention to provide a method of manufacturing a plate for a flat panel display that employs the above exposure method and to provide an exposure method and an exposure apparatus optimal for the manufacturing method of the plate.

One aspect of the present invention is an exposure method for exposing a plate by illuminating a mask with illumination light and using a mask pattern on the plate. The method includes scanning the plate relative to the mask in a scanning direction, which is an in-plane direction of the plate, and exposing the plate during the relative scanning. The relative exposing includes performing both a fine period exposure, which uses a fine period mask pattern formed in a first region of the mask, and a middle density exposure, which uses a middle density mask pattern formed in a second region of the mask. The first region and the second region are adjacent to each other in the scanning direction and expose the plate during the relative scanning.

A further aspect of the present invention is a method for manufacturing a plate for a flat panel display. The method includes an exposure step. At least part of the exposure step is performed by using an exposure method according to one aspect of the present invention.

Another aspect of the present invention is a method for manufacturing a plate for a flat panel display. The method includes forming a thin film transistor, and forming a source electrode and a drain electrode of the thin film transistor by using an exposure method according to one aspect of the present invention.

Still, another aspect of the present invention is an exposure apparatus for exposing a pattern on a plate. The exposure apparatus is provided with an optical unit including an illumination optical system and a projection optical system. A movable mechanism scans the plate relative to the optical unit in a scanning direction, which is an in-plane direction of the plate. A mask holding mechanism is capable of holding a mask on a first plane defined by the optical unit. The illumination optical system illuminates with illumination light a first region and a second region adjacently arranged in the scanning direction on the first plane. The projection optical system projects at least part of a region on the first plane that includes the first region and the second region.

Each aspect of the present invention forms fine patterns at a low cost when manufacturing a plate used as a display screen of a flat panel display. Further, the present invention manufactures a plate for a flat panel display at a low cost.

### BRIEF DESCRIPTION OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is a schematic perspective diagram of an exposure apparatus according to an embodiment of the present invention;

FIG. 2 is a schematic diagram showing a mask according to the embodiment of the present invention;

FIGS. 3(A) and 3(B) are diagrams showing the arrangement of projection optical systems and a plate according to the embodiment of the present invention, where FIG. 3(A) is a diagram showing the arrangement of the projection optical systems and FIG. 3(B) is a diagram showing exposure regions formed on the plate and exposed by the exposure apparatus;

FIG. 4 is a diagram showing one example of a mask applicable to an exposure method according to a first embodiment of the present invention;

FIG. 5 is a schematic diagram illustrating fine period exposure according to an embodiment of the present invention;

FIG. 6 is a schematic diagram illustrating middle density exposure according to an embodiment of the present invention;

FIG. 7 is a diagram illustrating an exposure method according to the first embodiment of the present invention;

FIG. 8 is a diagram showing a modification of an illumination optical system according to the embodiment of the present invention;

FIG. 9 is a diagram showing one example of a mask applicable to an exposure method according to a second embodiment of the present invention;

FIG. 10 is a diagram illustrating an exposure method according to the second embodiment of the present invention;

FIG. 11 is a diagram showing one example of a mask applicable to an exposure method according to a third embodiment of the present invention;

FIG. 12 is a diagram illustrating an exposure method according to the third embodiment of the present invention;

FIG. 13 is a diagram showing one example of a mask applicable to an exposure method according to a fourth embodiment of the present invention;

FIG. 14 is a diagram illustrating the exposure method according to the fourth embodiment of the present invention;

FIG. 15 is a diagram showing part of a plate for a liquid crystal display; and

FIG. 16 is a diagram illustrating a method for manufacturing a plate for a flat panel display according to an embodiment of the present invention.

### DESCRIPTION OF REFERENCE NUMERALS

IL illumination optical system
IM1 to IM3 illumination optical modules
M1 to M7 masks
PL projection optical system
P plate
PS plate stage
LM1 to LM2 linear motor movable elements
LG1 to LG2 linear motor fixed elements
BP base plate

### DETAILED DESCRIPTION OF THE INVENTION

An embodiment of the present invention will now be described with reference to the drawings. In this specification, a fine period mask pattern refers to a one-dimensional periodic mask pattern formed on a mask. The period of a fine period mask patters is fine and such that it about the same as the resolution limitation of a projection optical system with which the mask pattern is projected.

A middle density mask pattern refers to a periodic mask pattern formed on a mask with a period that is greater than or equal to 1.5 times the resolution limitation of a projection optical system with which the mask pattern is projected. The resolution limitation of the projection optical system is a value expressed by λ/NA, where λ represents the used wavelength and NA represents the numerical aperture of the projection optical system.

A pattern refers to the shape of illumination light that has illuminated a mask, or a bright-dark distribution of exposure light. A mask pattern refers to the shape of the distribution of light-transmitting portions and light-shielding portions formed on a mask or the shape of the distribution of one or more phase-shift light-transmission portions. An exposure pattern refers to the shape of the exposure distribution exposing a photosensitive material, such as a photoresist, formed on a plate. Further, a plate pattern refers to at least part of a conductive member, an insulation member, or a semiconductor member formed on a plate.

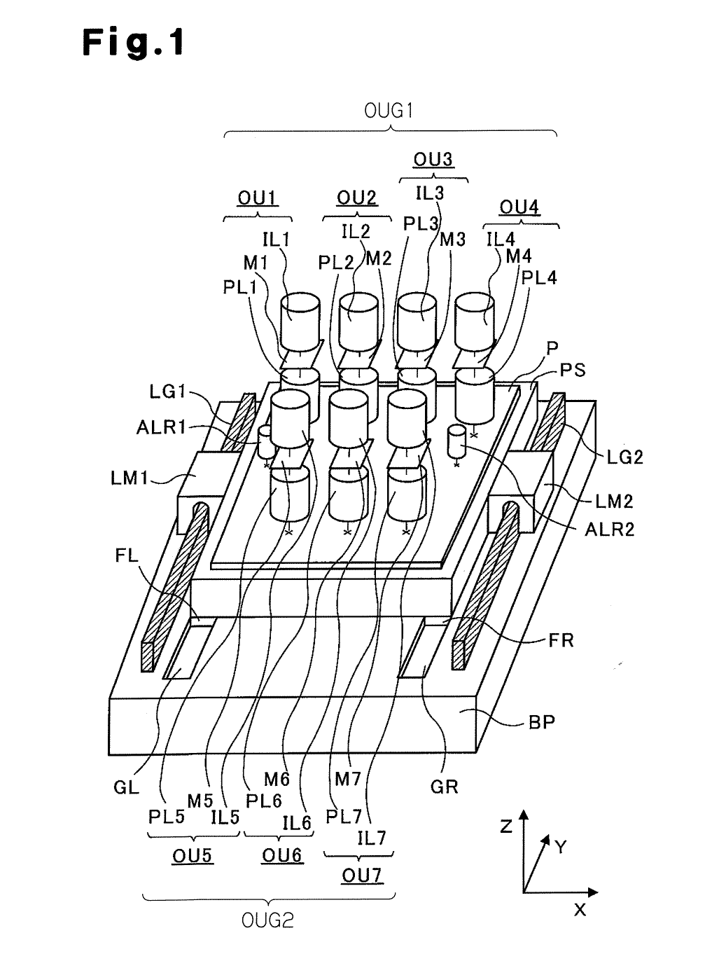

FIG. 1 is a schematic perspective view showing one example of an exposure apparatus according to an embodiment of the present invention. In FIG. 1, a plate stage PS supports a plate P, such as a glass plate. The plate P functions as a display screen of a flat panel display. A plurality of (seven in the present embodiment) optical units OU1 to OU7 are arranged above the plate stage PS (in a +Z direction as viewed in the drawing). The optical units OU1 to OU7 are used to form an exposure pattern on the plate P, which is supported on the plate stage PS. The optical units OU1 to OU7 are arranged in a zigzag along an X direction (non-scanning direction X), which is substantially orthogonal to a Y direction (scanning direction Y) as viewed in the drawing. The zigzag arrangement refers to an arrangement in which optical units are alternately arranged in a first line (+Y direction) and a second line side (−Y direction) along the X direction. For example, in FIG. 1, the optical units OU1 to OU4 are arranged at a predetermined interval at the first line side so as to form a first optical unit group OUG1. The optical units OU5 to OU7 are arranged at a predetermined interval at the second line side so as to form a second optical unit group OUG2.

An example of the optical unit OU1 to OU7 will now be described. For example, the optical unit OU1 includes a projection optical system PL1, which exposes a pattern on the plate P, and an illumination optical system IL1, which irradiates illumination light. The optical unit OU1 further includes a mask M1 arranged between the projection optical system PL1 and the illumination optical system IL1. The mask M1 is held on a mask stage (not shown). The projection optical system PL1 is an optical system that forms an image in a field of view on the mask M1, which is held on the mask stage, in an image field on the plate P. The illumination optical system IL1 is an optical system that illuminates the mask M1, which is supported on the mask stage, with illumination light, which is emitted from a light source, in a substantially uniform manner. The region illuminated on the mask M1 by the illumination optical system IL1 is all or part of a mask pattern region, which includes the mask pattern formed on the mask M1.

The number of the optical units (OU1 to OU7) is not limited to seven and may be any number including one.

The first optical unit group OUG1 and the second optical unit group OUG are spaced from each other by a predetermined interval in the Y direction so as to prevent mechanical interference between the illumination optical systems IL1 to IL7 that may occur due to the dimensions of the illumination optical systems IL1 to IL7, especially in the Y direction. However, to improve the processing capability of the exposure apparatus by eliminating unnecessary scanning operations and reducing the scanning time, it is preferred that the first optical unit group OUG1 and the second optical unit group OUG2 be arranged as close as possible in the Y direction without causing interference between the illumination optical systems IL1 to IL7.

The plate stage PS is movable along guide grooves GL and GR formed in a base plate BP in the Y direction, which is one of the in-plane directions of the plate P, as viewed in the drawing. More specifically, the plate stage PS is one example of a movable mechanism that enables the plate P to be scanned relative to the optical units OU1 to OU7. In the Y direction, the plate stage PS is moved and aligned. A linear motor system including movable elements LM2 and LM2, which are arranged on the plate stage PS, and fixed elements LG1 and LG2, which are arranged on the base plate BP, and a position controlling system (not shown) moves and positions the plate stage PS in the Y direction and finely moves and positions the plate stage PS in the X direction.

While the above-described exposure apparatus performs exposure, the plate P is moved in the Y direction by the linear motor system. This causes the plate P to be scanned relative to the optical units OU1 to OU7 in the Y direction, which is an in-plane direction of the plate P. In other words, the plate P is scanned and exposed. Through the scanning exposure, an exposure pattern is formed on almost the entire surface of the plate P in the Y direction even when using a mask of which outer shape is smaller than the outer shape of the plate. The relative scanning is performed by moving only the plate in the Y direction while the optical units OU1 to OU7 are fixed. In other words, through the relative scanning, an exposure pattern is formed on the plate while keeping the optical units OU1 to OU7 fixed and moving only the plate in the Y direction to expose the pattern on the plate.

The axes of the XYZ coordinates are used in FIG. 1 to facilitate description and it is apparent that any coordinate axes may be used for the exposure apparatus. In the drawings following FIG. 1, the directions of the XYZ coordinate axes used for embodiments of exposure apparatuses are the same as the directions of the XYZ coordinate axes used in FIG. 1.

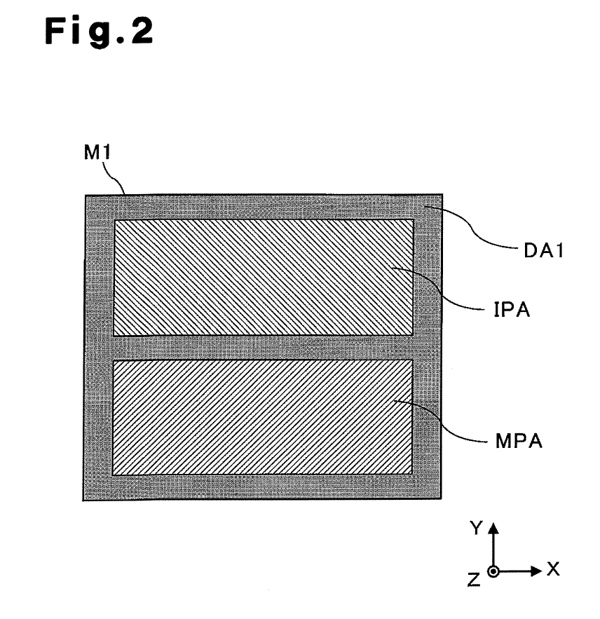

The mask used in the present embodiment will now be described with reference to FIG. 2. The mask M1 is formed by a light-transmitting plate, such as a glass plate. As shown in FIG. 2, the mask M1 includes a fine period mask pattern region IPA and a middle density mask pattern region MPA, which are defined by a light-shielding area DA1. The light-shielding area DA1 is formed by a light-shielding film, such as a chromium film. The fine period mask pattern region IPA and the middle density mask pattern region MPA are arranged adjacent to each other in the Y direction. The fine period mask pattern region IPA includes light-transmitting portions and light-shielding portions, which form a mask pattern. The middle density pattern region MPA includes light-transmitting portions and light-shielding portions, which form a mask pattern. Some of the light-transmitting portions in the fine period mask pattern region IPA may further include phase members (e.g., dielectric films). In such a case, a phase difference of (2n+1)n[rad] (where n is an integer) is produced between the illumination light passing through a phase member and illumination light passed through a light-transmitting portion that does not include a phase member. The mask patterns formed in the fine period mask pattern region IPA and the middle density mask pattern region MPA will be described in detail later.

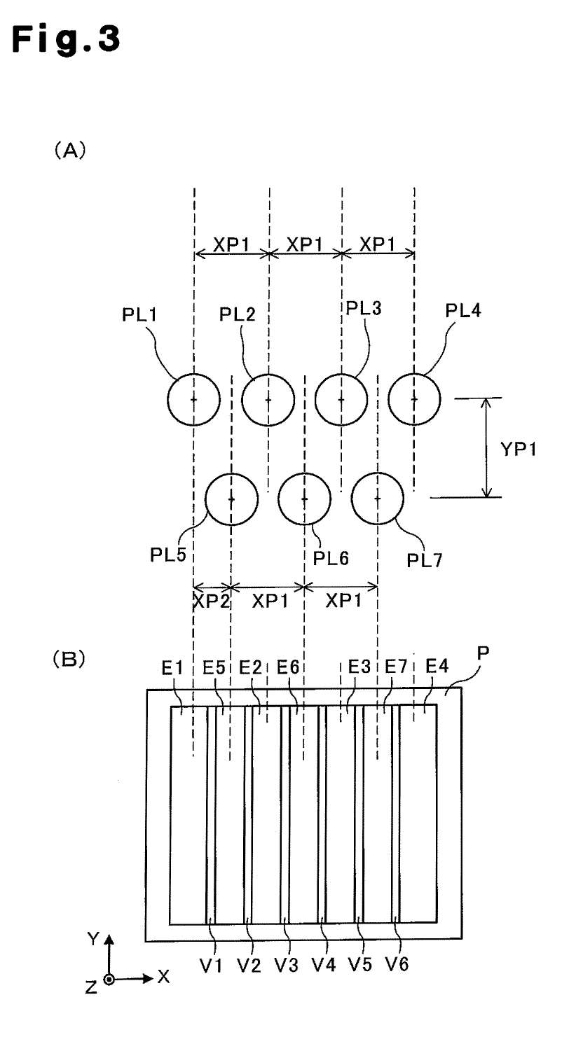

The positional relationship between the projection optical systems PL1 to PL7 and the plate P in XY directions will now be described in detail with reference to FIGS. 3(A) and 3(B). As shown in FIG. 3(A), the projection optical systems PL1 to PL4 are arranged at an interval XP1 in the X direction on the same Y coordinate position. The remaining three projection optical systems PL5 to PL7 are arranged at an interval XP1 in the X direction and spaced from the projection optical systems PL1 to PL4 by interval YP1 in the Y direction. The X coordinate of the projection optical system PL1 is located apart from the X coordinate of the projection optical system P5 by an interval XP2, which is one half the interval XP1.

As described above, the exposure apparatus of the present embodiment exposes the plate P while scanning the plate P relative to the optical units OU1 to OU7 in the Y direction. During the scanning exposure, the projection optical systems PL1 to PL7 form a plurality of partial exposure regions, in which patterns are exposed, on the plate P. The partial exposure regions each extend in the Y direction and have a predetermined width in the X direction. In FIG. 3, the partial regions E1, E2, E3, E4, E5, E6, and E7 are regions in which exposure patterns are respectively formed by the projection optical systems PL1, PL2, PL3, PL4, PL5, PL6, and PL7.

Overlapping regions V1, V2, V3, V4, V5, and V6 may be formed between the partial regions on the plate P. In such a case, the overlapping region V1 is, for example, a region in which an exposure pattern is formed in an overlapped manner by the two projection optical systems PL1 and PL5, which correspond to the partial regions E1 and E5 that are adjacent to the overlapping region V1. In each of the other overlapping regions V2 to V6, an exposure pattern is formed in an overlapped manner by two of the projection optical systems PL2 to PL7 that are adjacent to each other in the X direction. The overlapping regions V1 to V6 will be described in detail later.

An exposure performed at one position in the partial region E1 will now be described. First, a case in which an exposure pattern is formed on the plate P while the plate P is scanned relative to the optical units OU1 to OU7 in the +Y direction will be described. In this case, due to the positional relationship between the fine period mask pattern region IPA and the middle density mask pattern region MPA on the mask M1, which is arranged on the optical unit OU1, the pattern of the fine period mask pattern region IPA is first formed at an exposure target position on the plate P. As the plate P moves and the exposure target position on the plate P reaches a position under the middle density mask pattern region MPA, the pattern of the middle density mask pattern region MPA is formed.

Accordingly, the partial region E1 is subjected to composite exposure (double exposure) by the exposure of the pattern of the fine period mask pattern region IPA and exposure of the pattern of the middle density mask pattern MPA. When the exposure is performed while the plate P is being scanned in the −Y direction, the composite exposure (or double exposure) is performed in the same manner although the pattern of the fine period mask pattern region IPA and the pattern of the middle density mask pattern region MPA are exposed in a reversed order. Such exposure is also performed for the other partial regions E2 to E7 in the same manner as the partial region E1.

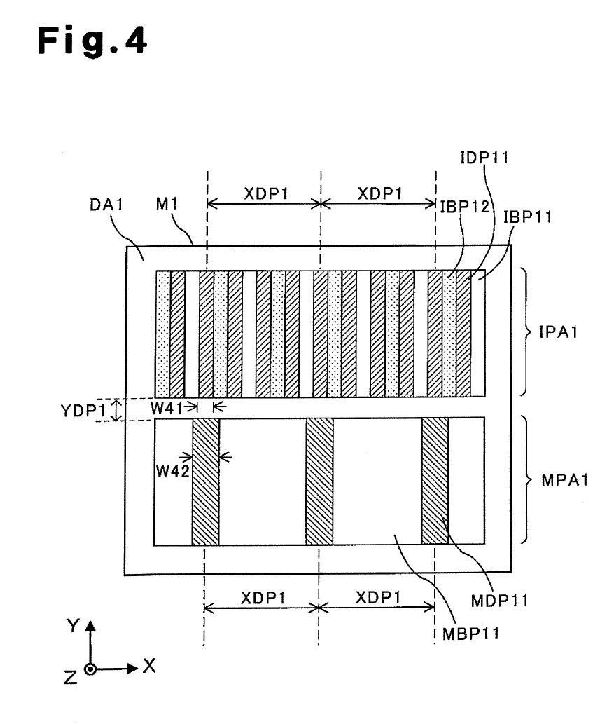

An example of the masks M1 to M7 that are applicable to the exposure apparatus of the present embodiment will now be described. FIG. 4 is a diagram showing the structure of the mask M1 on which part of the mask pattern of the exposure apparatus of the present embodiment is formed. As shown in FIG. 4, a first region IPAL includes a mask pattern formed by light-transmitting portions IBP11 and IBP12, which allow the passage of light beams of a predetermined wavelength (e.g., i-line and KrF excimer laser), and light-shielding portions IDP11 (chromium film etc.). A second region MPA1 includes a mask pattern formed by light-transmitting portions MBP11, which allow passage of light beams of a predetermined wavelength (e.g., i-line and KrF excimer laser), and light-shielding portions MDP11 (chromium film etc.).

The mask pattern formed in the first region IPA1 is a fine period mask pattern. The mask pattern formed in the second region MPA1 is a middle density mask pattern.

In the first region IPA1, the light-transmitting portions IBP11 and IBP12 and the light-shielding portions IDP11 are arranged in the X direction, which is substantially orthogonal to the scanning direction. In the second region IPA1, the light-transmitting portions MBP11 and the light-shielding portions MDP11 are arranged in the X direction, which is substantially orthogonal to the scanning direction. In the mask pattern formed in the first region IPA1, the light-transmitting portions IBP12 includes phase members PSP (e.g., dielectric films). The phase members PSP each have a film thickness that changes the phase of passing light by, for example, π[red] . More specifically, a phase difference of (2n+1)π[rad] (where n is an integer) is produced between the illumination light passing through the phase member PSP and illumination light passing through the light-transmitting portion IBP11, which does not include a phase member PSP.

The mask pattern formed in the second region MPA1 includes light-shielding portions MDP11 at positions corresponding to predetermined light-shielding portions IDP11 formed in the first region IPA1. More specifically, the light-shielding portions MDP11 are each formed in the second region MPA1 so that the light-shielding portion MDP11 and the corresponding light-shielding portion IDP11 in the first region IPA1 have widthwise center lines in the X direction that are aligned with each other.

The light-shielding portions MDP11 of the second region MPA1 are arranged at an interval XDP1 in the X direction. Each light-shielding portion MDP11 of the second region MPA1 has a width W42 in the X direction that is substantially one to two times greater than a width W41 in the X direction of each light-shielding portion IDP11 in the first region IPA1. The number of the light-shielding portions MDP11 formed in the second region MPA1 is set in accordance with a predetermined number of exposure patterns that are formed on the plate P.

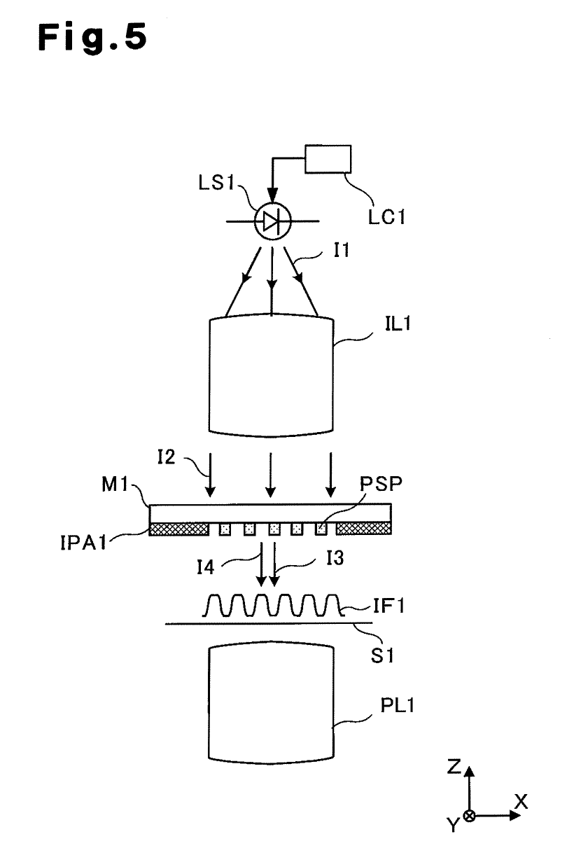

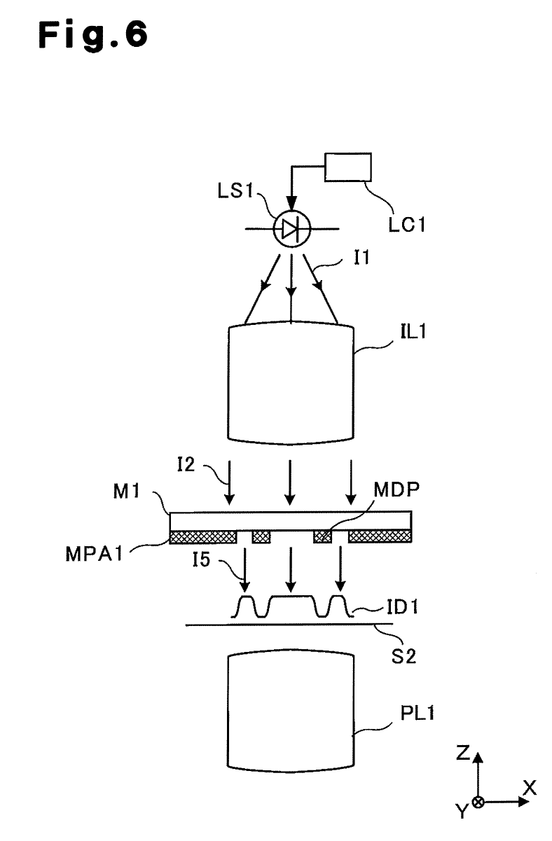

The fine period exposure and the middle density exposure performed by the exposure apparatus of the present embodiment will now be described with reference to FIGS. 5 and 6. FIG. 5 is a schematic cross-sectional view illustrating the fine period exposure performed with the mask M1. The mask M1 includes the first region IPA1 and the second region MPA1. Illumination light I1, which is emitted from a light source LS1, is shaped by the illumination optical system IL1 into substantially uniform illumination light I2. The light source LS1 may be, for example, a laser, such as a semiconductor laser, or an illumination diode etc. A light controller LC1 controls the emission of light from the light source LS1. The mask M1, which is illuminated with the illumination light I2, is arranged under the illumination optical system IL1.

When the first region IPA1 of the mask M1 is illuminated with the illumination light I2, illumination light I3 and illumination light I4 are generated. The illumination light I3 is the light that passes through the light-transmitting portions IBP12, which includes the phase members PSP. The illumination light I4 is the light that passes through the light-transmitting portions IBP11, which does not include phase members. The illumination light I3 and the illumination light I4 form interference fringes IF1 on a plane S1 defined in the vicinity of the mask M1. As a result, an exposure pattern having the interference fringes IF1, of which periodic direction coincides with the X direction, is formed on the plate P by the projection optical system PL1. Since the periodic direction of the interference fringes IF1 coincides with the X direction, a bright-dark pattern of the interference fringes is parallel to the Y direction, which is orthogonal to the X direction, that is, parallel to the scanning direction.

The exposure apparatus of the present embodiment exposes the plate P while scanning the plate P relative to the optical units OU1 to OU7 in the Y direction. Thus, the bright-dark distribution of the interference fringes IF1 is enlarged in the Y direction to form an exposure pattern on the plate P through the above-described fine period exposure. The periodic direction of the interference fringes IF1 coincides with the X direction. This prevents the contrast of the interference fringes IF1 from being lowered by the scanning exposure performed in the direction orthogonal to the periodic direction of the interference fringes IF1.

FIG. 6 is a schematic cross-sectional diagram illustrating the middle density exposure that is performed using the mask M1. The mask M1 includes the first region IPA1 and the second region MPA1. The light controller LC1, the light source LS1, the illumination optical system IL1, and the like are the same as in FIG. 5 when used to perform the fine period exposure. The middle density exposure differs from the fine period exposure illustrated in FIG. 5 in that the middle density exposure does not use the first region IPA1 of the mask M1 and uses the second region MPA1 instead. As shown in FIG. 6, when the second region MPA1 of the mask M1 is illuminated with the illumination light I2, the illumination light I2 passes through portions of the mask M1 corresponding to the light-transmitting portions MBP11 and does not pass through other portions of the mask M1 (portions corresponding to the light-shielding portions MDP11). This forms a light distribution ID1 of the illumination light I5 on a plane S1, which is defined in the vicinity of the mask M1, in accordance with the shape of the light-transmitting portions MBP11. In this case, a plurality of beam spots of the illumination light I5 are formed on the plate P. The number of beam spots is variable in accordance with the number of the light-transmitting portions MBP11 or the light-shielding portions MDP11 of the mask M1.

The exposure apparatus of the present embodiment exposes the plate P while scanning the plate P relative to the optical units OU1 to OU7 in the Y direction. This enlarges the shapes of the beam spots formed by the light-transmitting portions MBP11. The enlarged beam spots are transferred as an exposure pattern onto the plate P.

While the plate P is being scanned in the Y direction, the emission of light from the light source, which emits illumination light into the illumination optical systems IL1 to IL7, is controlled in accordance with the positions of the optical units OU1 to OU7 relative to the plate P so as to enable the shape of the pattern exposed on the plate P to be varied in the Y direction. A switching mechanism for switching between emitted and non-emitted states of the illumination light in a time-sharing manner is not limited to the above mechanism that controls the emission of light from the light source. The switching mechanism may also be formed by a mechanical shutter or an electric shutter using an electric optical element arranged in an optical path between the light source and the plate P.

To change the positions and shapes of beam spots exposing the plate P, it is preferable that the exposure apparatus of the present embodiment includes an exchanging mechanism that enables the mounting of a plurality of masks in a exchangeable manner. The exchanging mechanism may include, for example, a holding mechanism (e.g., a mask stage) (not shown) for holding the mask M1 and a mechanism for transporting the mask M1 to the holding mechanism. In this case, it is preferable that the holding mechanism includes a reference pin and a position sensor for positioning the mask M1.

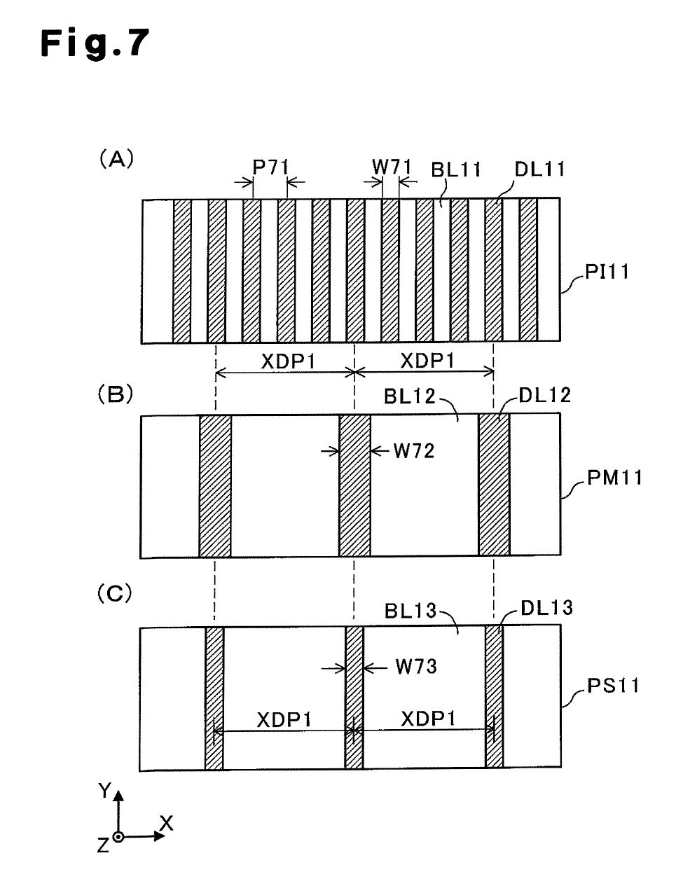

As described above, the exposure apparatus of the present embodiment performs composite exposure with the fine period mask pattern formed in the first region IPA1 and the middle density mask pattern formed in the second region MPA1 of each of the masks M1 to M7. This enables highly accurate exposure of exposure patterns. An exposure method according to a first embodiment of the present invention using the exposure apparatus of the present embodiment ultimately forming an exposure pattern (composite pattern) on the plate P will now be described with reference to FIG. 7(A). In the embodiment, positive photoresist is used as the resist applied to the plate P.

FIG. 7(A) shows part of an exposure pattern formed on the plate P by illuminating with illumination light the first region IPA1 of the mask M1 including the phase members PSP shown in FIG. 4. Shaded portions in the drawing indicate portions where the amount of exposure light is less than a reference exposure light amount, which is the amount of exposure light necessary to expose the resist. Such portions are hereafter referred to as dark portions. Portions that are not shaded in the drawing indicate portions where the amount of exposure light is greater than the reference exposure amount. These portions are hereafter referred to as bright portions.

An exposure pattern PI11, which is formed by illuminating the first region IPA1 of the mask M1 including the phase members PSP, includes bright line portions BL11 and dark line portions DL11 that are arranged in the X direction at a center interval P71. Each dark line portion DL11 has a width W71 in the X direction.

FIG. 7(B) shows part of an exposure pattern PM11, which is exposed on the plate P by illuminating the second region MPA1 of the mask M1 shown in FIG. 4 with illumination light. The plate P is exposed while being scanned relative to the optical unit OU1 in the Y direction. Thus, during the scanning exposure, portions of the plate P that have the same X coordinates as the X coordinates of the light-transmitting portions MBP11 are illuminated with exposure light and become bright portions BL12. During the scanning exposure, portions of the plate P that have the same X coordinates as the X coordinates of the light-shielding portions MDP11 are not illuminated with exposure light and become dark portions DL12. Each dark portion DL12 has a width W72 in the X direction that is substantially equal to the width W42 of each light-shielding portion MDP11 in the X direction. The dark portions DL12 are arranged in the X direction at a center interval that is the same as the center interval XDP1 between the light-shielding portions MDP11 in the X direction.

An exposure pattern PS11, which is a composite pattern of the exposure pattern PI11 and the exposure pattern PM11 described above, will now be described with reference to FIG. 7(C). Bright portions of the exposure pattern formed on the plate P by illuminating the first region IPA1 or the second region MPA1 with illumination light define bright portions BL13 in the composite exposure pattern PS11. Accordingly, dark portions in the exposure pattern PS11 are formed where the exposure pattern PI11 and the exposure pattern PM11 are both dark. More specifically, in the exposure method of the first embodiment, every predetermined number of specific dark line portions DL11, such as every four dark line portions DL11, in the exposure pattern PI11 formed during the fine period exposure are left in the exposure pattern PS11 as dark line portions DL13.

In the exposure apparatus of the embodiment, specific dark portions in the interference fringes IF1 formed by the fine period exposure are overlapped on the plate P with the dark portions of the light distribution ID1 formed by the middle density exposure. The specific dark portions in the interference fringes IF1 have a width that is narrower than the width of the dark portions in the light distribution ID1. Thus, the width of the dark line portions DL13 is determined by the width of the specific dark portions in the interference fringes IF1. Accordingly, finer dark line portions DL13 can be formed by increasing the amount of exposure light during the fine period exposure and narrowing the width of the dark portions in the light distribution ID1.

As described above, in the exposure method of the first embodiment, finer patterns are formed with high accuracy through the fine period exposure and the middle density exposure, and predetermined ones of the patterns can be selected to remain.

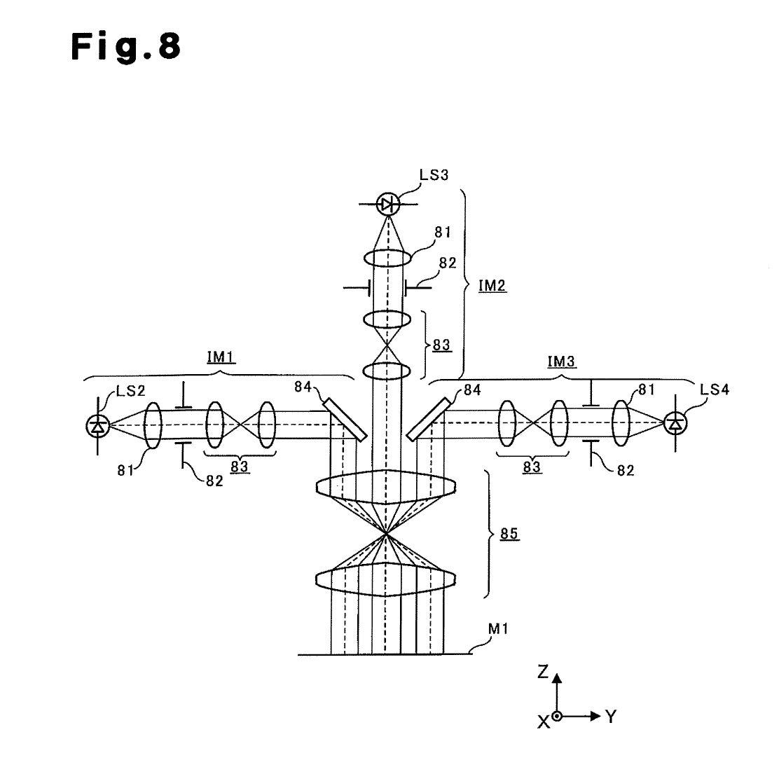

An exposure method according to a second embodiment of the present invention using the exposure apparatus of the embodiment to ultimately form an exposure pattern (composite pattern) on the plate P will now be described with reference to FIGS. 8, FIG. 9, and 10. The exposure method of the second embodiment uses an illumination optical system shown in FIG. 8 as one example of the illumination optical system IL1 shown in FIG. 1. The illumination optical system shown in FIG. 8 includes illumination optical modules IM1 to IM3 and a relay optical system 85. The illumination optical modules IM1 to IM3 illuminate a mask pattern region of a mask M1. As shown in FIG. 8, each of the illumination optical modules IM1 to IM3 illuminates a different illumination region in the Y direction. For example, in the illumination optical module IM1, a light beam emitted from a light source LS2 is collimated by a collimating lens 81. The collimated light beam then passes through a stop 82 and enters a relay lens group 83. The light beam entering the relay lens group 83 is deflected by a reflection mirror 84. The deflected light beam enters the relay optical system 85, and illuminates a predetermined mask pattern region of the mask M1. The illumination optical module IM2, which is identical to the illumination optical module IM1 except in that the reflection mirror 84 is eliminated, will not be described. The illumination optical module IM3, which is also identical to the illumination optical module IM1, will not be described. The relay optical system 85 may be eliminated from the illumination optical system shown in FIG. 8.

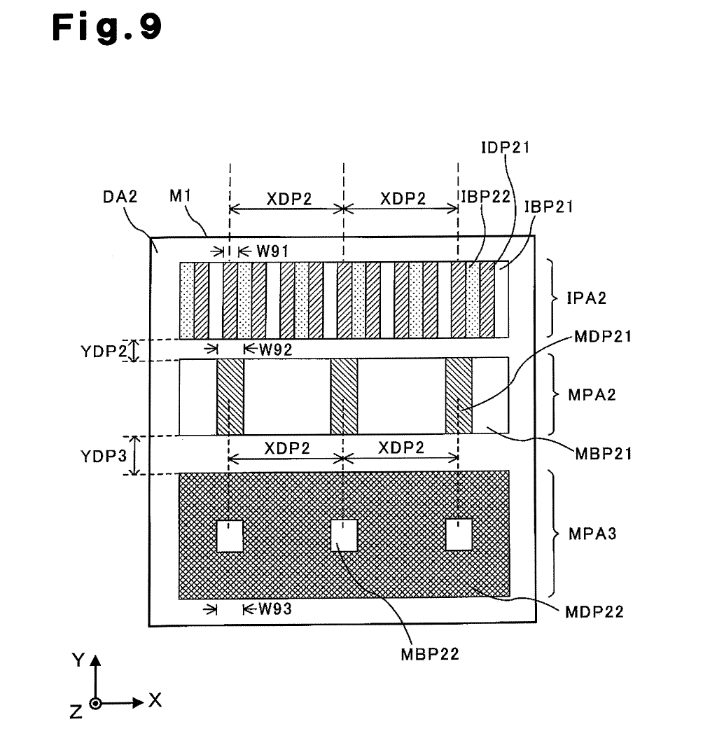

The structure of a mask applicable to the exposure method of the second embodiment will now be described. FIG. 9 is a diagram showing one example of the structure of the mask M1 on which is formed part of the mask pattern of the second embodiment. A first region IPA2 and a second region MPA2 of the mask M1 are substantially the same as the first and second regions of the mask M1 described in the first embodiment. The mask M1 includes three pattern regions (e.g., the first region IPA2, the second region MPA2, and a third region MPA3) that are arranged at predetermined intervals in the Y direction. Each of the three pattern regions of the mask M1 is formed by either a fine period mask pattern or a middle density mask pattern. The same mask pattern as the fine period mask pattern shown in FIG. 4 is formed in the first region IPA2 of the mask M1. The same mask pattern as the middle density mask pattern shown in FIG. 4 is formed in the second region MPA2 of the mask M1.

A mask pattern (middle density mask pattern) including light-transmitting portions MBP22 and a light-shielding portion MDP22 is formed in the third region MPA3 of the mask M1. In one example, a plurality of rectangular light-transmitting portions MBP22 are each arranged in the X direction in the third region MPA3. The center interval between the light-transmitting portions MBP22 in the X direction is set to be the same as the center interval XDP2 between the light-shielding portions MDP21 of the second region MPA2. Each light-transmitting portion MBP22 has a width W93 in the X direction that is set in a range of about 1.5 to 2.5 times the width W91 of each light-shielding portion IDP21 in the first region IPA2.

For example, among the illumination optical modules IM1 to IM3 described above, the illumination optical module IM1 is an optical system that illuminates the first region IPA2 of the mask M1, the illumination optical module IM2 is an optical system that illuminates the second region MPA2 of the mask M1, and the illumination optical module IM3 is an optical system that illuminates the third region MPA3 of the mask M1.

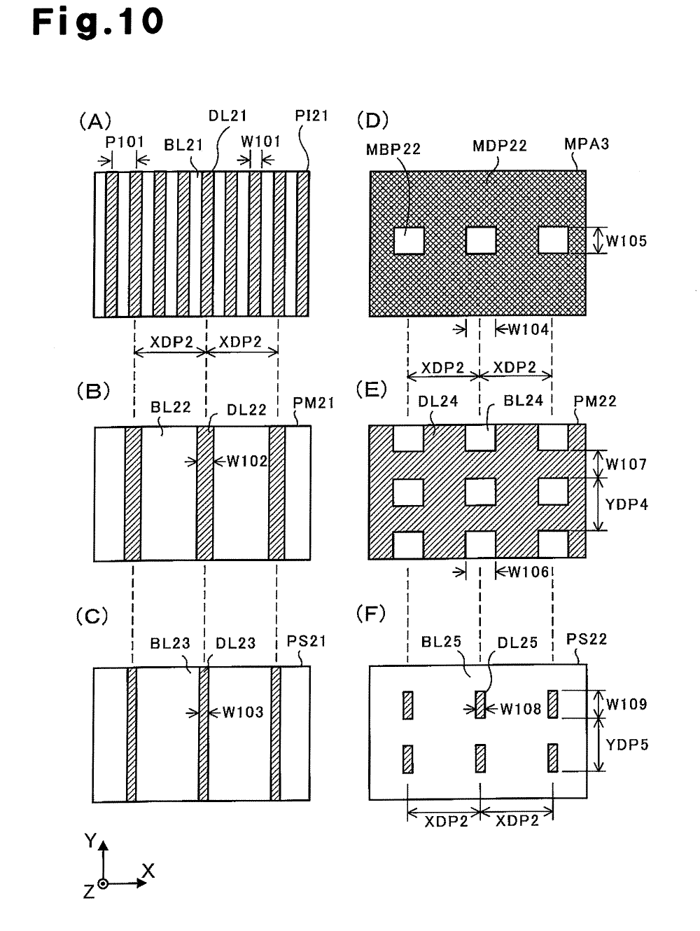

In the second embodiment, an exposure pattern that is formed on the plate P by the projection optical system PL1 will now be described. The exposure pattern is basically the same as the pattern formed by the exposure method of the first embodiment. FIG. 10(A) shows part of an exposure pattern PI21 that is formed on the plate P by illuminating the first region IPA2 of the mask M1 shown in FIG. 9 with illumination light. The mask pattern formed in the first region IPA2 of the mask M1 is substantially the same as the mask pattern formed in the first region IPA1 of the mask M1 shown in FIG. 4. Thus, the exposure pattern PI21 is also basically the same as the exposure pattern PI11 shown in FIG. 7(A). More specifically, the exposure pattern PI21 formed on the plate P includes bright line portions BL21 and dark line portions DL21 that are arranged in the X direction at center intervals P101. Each dark line portion DL21 has a width W101 in the X direction.

FIG. 10(B) shows part of an exposure pattern PM21, which is formed on the plate P by illuminating the second region MPA2 of the mask M1 shown in FIG. 9 with illumination light. The mask pattern formed in the second region MPA2 of the mask M1 is substantially the same as the mask pattern formed in the second region MPA1 of the mask M1 shown in FIG. 4. Thus, the exposure pattern PM21 is also basically the same as the exposure pattern PM11 shown in FIG. 7(B). More specifically, during the scanning exposure, portions of the plate P that have the same X coordinates as the X coordinates of the light-transmitting portions MBP21 are illuminated with exposure light and become bright portions BL22. During the scanning exposure, portions of the plate P that have the same X coordinates as the X coordinates of the light-shielding portions MDP21 are not illuminated with exposure light and thus become dark portions DL22. Each dark portion DL22 has a width W102 in the X direction that is substantially equal to the width W92 in the X direction of each light-shielding portion MDP21 of the mask M1. The center interval between the dark portions in the X direction is the same as the center interval XDP2 between the light-shielding portions MDP21 in the X direction.

An exposure pattern PS21, which is a composite pattern of the exposure pattern PI21 and the exposure pattern PM21 described above, will now be described with reference to FIG. 10(C). The mask pattern formed in the first region IPA2 and the mask pattern formed in the second region MPA2 are substantially the same as the mask pattern formed in the first region IPA1 and the mask pattern formed in the second region MPA1 shown in FIG. 4. Thus, the exposure pattern PS21 is also basically the same as the exposure pattern PS11 shown in FIG. 7(C). More specifically, the exposure pattern PS21 is formed by every predetermined number of specific dark line portions DL21, such as every four dark line portions DL21, in the exposure pattern PI21 formed during the fine period exposure are left in the exposure pattern PS21 as dark line portions DL23.

FIG. 10(D) shows part of a mask pattern that includes light-transmitting portions MBP22 and a light-shielding portion MDP22 formed in the third region MPA3 of the mask M1 by the exposure method of the second embodiment (substantially the same as the mask pattern formed in the third region MPA3 in FIG. 9). When the plate P is exposed by the projection optical system PL1, for example, a light source LS4 of the illumination optical module IM3, which illuminates the third region MPA3, repetitively emits light in a time-sharing manner in cooperation with relative scanning of the plate P. More specifically, a control mechanism (not shown) provides instructions to the light controller LC4 (not shown) while the plate P is being scanned and exposed to repetitively start and stop the emission of light from the light source LS4 whenever a predetermined time elapses or whenever a predetermined distance is exposed. As a result, the illumination optical module IM3 repetitively performs illumination and non-illumination of the third region MPA3 in the mask in a time-sharing manner. Consequently, the projection optical system PL1 repetitively performs illumination and non-illumination of the plate P with exposure light.

FIG. 10(E) shows one example of an exposure pattern PM22 formed on the plate P through the exposure described above. Discrete rectangular regions arranged under the light-transmitting portions MBP22 when the light source LS4 emits light become bright portions BL24. The remaining portions form a dark portion DL24. Each bright portion BL24 has a width W106 in the X direction that is substantially equal to the width W104 of each light-transmitting portion MBP22 in the X direction. A center interval YDP4 between the bright portions BL24 in the Y direction is determined by the time interval at which the light controller LC4 (not shown) repetitively stops the emission of light from the light source LS4 and by the scanning speed of the plate stage PS, which supports the plate P. Accordingly, the time interval at which the light source LS4 stops emitting light and the scanning speed of the plate stage PS may be controlled to control the center interval YDP4. Further, the duty ratio of the emission time and non-emission time of the light source LS4 can be controlled to control the Y direction width W107 of the dark portion DL24 between the bright portions BL24 in the Y direction.

It is preferable that each light-transmitting portion MBP22 in the third region MPA3 of the mask M1 have a width W105 in the Y direction that is less than the Y direction width of the dark portion BL24 in the exposure pattern 22, or less than a value obtained by subtracting the Y direction width W107 between bright portions BL24 from the center interval YDP4 of the bright portions BL24. If the width W105 of the light-transmitting portions in the Y direction were to be greater, it would be difficult to form the bright portions BL24 with the desired width in the Y direction.

An exposure pattern PS22, which is a composite pattern of the exposure pattern PS21 and the exposure pattern PM22 described above, will now be described with reference to FIG. 10 (F). In the second embodiment, bright portions in exposure patterns formed by illuminating any of the first region IPA2, the second region MPA2, and the third region MPA3 with illumination light also become bright portions BL25 in the exposure pattern PS22, which is a composite pattern. Thus, only portions that are dark in both of the exposure pattern PS21 and the exposure pattern PM22 are become dark portions in the exposure pattern PS22. More specifically, in the exposure method of the second embodiment, every predetermined number of specific dark line portions DL21, such as every four dark line portions DL21, in the exposure pattern PI21 formed during the fine period exposure are selected. Then, only specific regions of the selected dark line portions DL21 in the Y direction are used to form dark line portions DL25 as the dark portions ultimately left on the plate P.

As described above, in the exposure method of the second embodiment, finer patterns are formed with high accuracy through the fine period exposure and the middle density exposure. Further, exposure may be performed to selectively leave desired patterns and restrict the desired patterns to specific regions having a predetermined width in the Y direction.

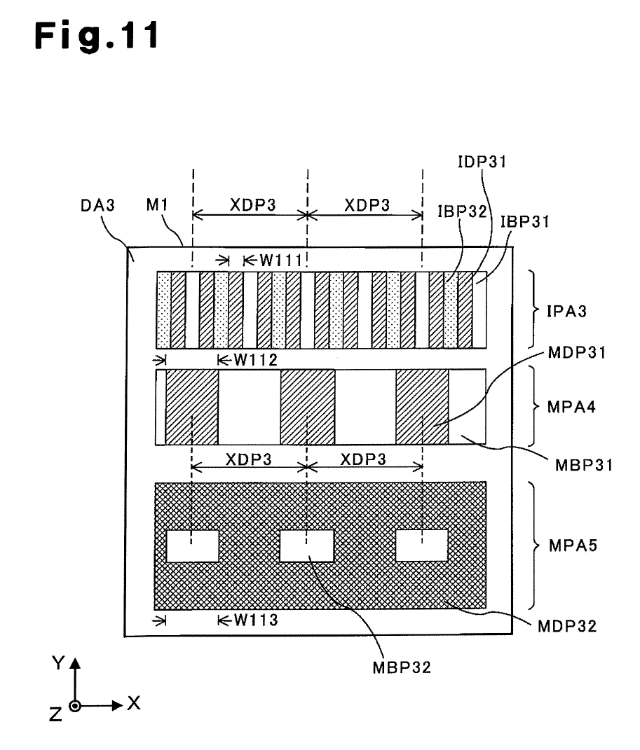

An exposure method according to a third embodiment of the present invention using the exposure apparatus of the embodiment to ultimately form an exposure pattern (composite pattern) on the plate P will now be described with reference to FIGS. 11 to 14. The exposure method of the third embodiment has many features similar to the exposure method of the second embodiment described above. Thus, the third embodiment will be described focusing only on the differences from the exposure method of the second embodiment. In the same manner as in the second embodiment, the third embodiment uses the illumination optical system shown in FIG. 8.

The structure of a mask applicable to the exposure method of the third embodiment will now be described. FIG. 11 shows one example of the structure of a mask M1 on which part of a mask pattern is formed by the exposure method of the third embodiment. The mask M1 includes a first region IPA3, a second region MPA4, and a third region MPA5 that are basically the same as the first, second, and third regions of the mask M1 applicable to the exposure method of the second embodiment shown in FIG. 9. The first region IPA3 of the mask M1 includes light-transmitting portions IBP31 and IBP32 and light-shielding portions IDP31, which form a mask pattern. In the same manner as the first region IPA2 shown in FIG. 9, light-transmitting portions IBP32 of the first region IPA3 include phase members PSP. As shown in FIG. 11, each light-transmitting portion IBP32, which includes a phase member PSP, is located between two light-transmitting portions IBP31, which do not include the phase members PSP, in the X direction.

The second region MPA4 of the mask M1 includes light-transmitting portions MBP31 and light-shielding portions MDP31, which form a mask pattern. The light-shielding portions MDP31 in the second region MPA4 are arranged at positions corresponding to predetermined light-shielding portions IDP31 in the first region IPA3. More specifically, the light-shielding portions MDP31 are each formed in the second region MPA4 so that the light-shielding portion MDP31 and the corresponding light-transmitting portions IBP31 in the first region IPA3 have widthwise center lines in the X direction that are aligned with each other. The number of the light-shielding portions MDP31 formed in the second region MPA4 is set in accordance with a predetermined number of exposure patterns formed on the plate P. Each light-shielding portion MDP31 has a width W112 in the X direction that is set in a range of about 1.5 to 2.0 times the width Wlll of each light-shielding portion IDP31 in the first region IPA3.

A mask pattern including light-transmitting portions MBP32 and a light-shielding portion MDP32 is formed in the third region MPA5 of the mask M1. In one example, a plurality of rectangular light-transmitting portions MBP32 are each arranged in the X direction. The center interval between the light-transmitting portions MBP32 in the X direction is set to be the same as the center interval XDP3 between the light-shielding portions MDP31 of the second region MPA4. Each light-transmitting portion MBP32 has a width W113 in the X direction that is set to be substantially the same as the width W112 of each light-shielding portion MDP31 in the second region MPA4.

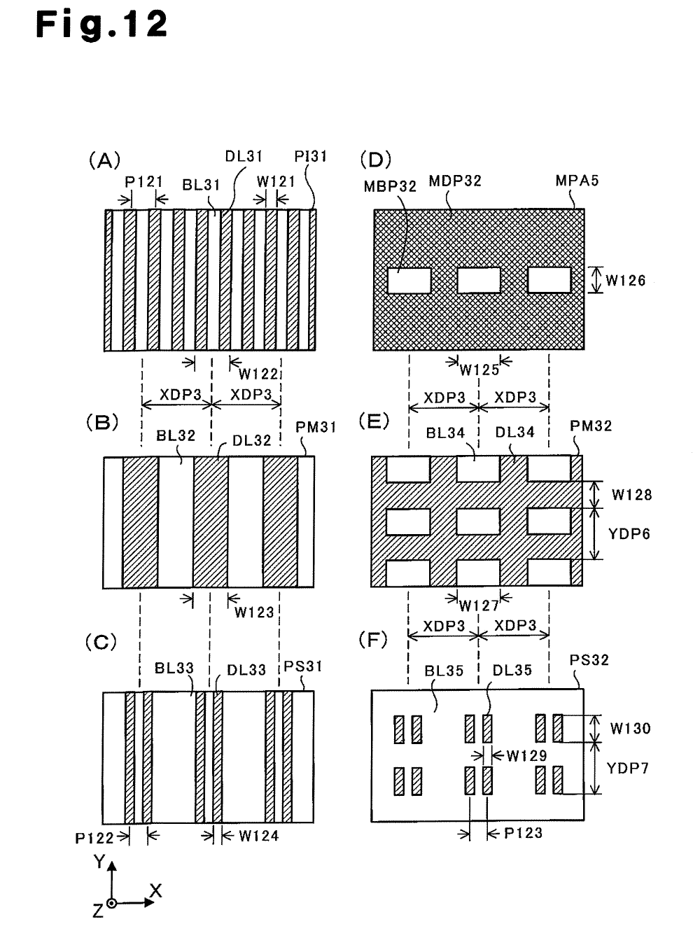

An exposure pattern formed on the plate P by the projection optical system PL1 in the third embodiment will now be described. The exposure pattern is basically the same as the pattern formed by the exposure method of the second embodiment. FIG. 12(A) shows part of an exposure pattern PI31, which is formed on the plate P by illuminating the first region IPA3 of the mask M1 shown in FIG. 11 with illumination light. The exposure pattern PI31 formed on the plate P includes bright line portions BL31 and dark line portions DL31 that are arranged in the X direction at a center interval P121. Each dark line portion DL31 has a width W121 in the X direction.

FIG. 12(B) is a diagram showing part of an exposure pattern PM31, which is formed on the plate P by illuminating the second region MPA4 of the mask M1 shown in FIG. 11 with illumination light. The plate P is exposed while being scanned relative to the mask M1 in the Y direction. During the scanning exposure, portions of the plate P that have the same X coordinates as the X coordinates of the light-transmitting portions MBP31 are illuminated with exposure light and become bright portions BL32. During the scanning exposure, portions of the plate P that have the same X coordinates as the X coordinates of the light-shielding portions MDP31 are not illuminated with exposure light and become dark portions DL32. Each dark portion DL32 has a width W123 in the X direction that is substantially equal to the width W112 of each light-shielding portion MDP31 in the X direction. The center interval between the dark portions in the X direction is the same as the center interval XDP3 between the light-shielding portions MDP31 in the X direction. More specifically, the dark portions DL32 are formed so that specific bright portions BL31 in the exposure pattern PI31 formed by the fine period exposure and the dark portions DL32 have widthwise center lines in the X direction that are aligned with each other.

An exposure pattern PS31, which is a composite pattern of the exposure pattern PI31 and the exposure pattern PM31 described above, will now be described with reference to FIG. 12(C). Portions that are bright in the exposure pattern formed on the plate P by illuminating any one of the first region IPA3 and the second region MPA4 become bright portions BL33 in the composite exposure pattern PS31. Accordingly, dark portions in the exposure pattern PS31 are restricted to portions that are dark in both of the exposure pattern PI31 and the exposure pattern PM31. More specifically, in the exposure method of the third embodiment, in every predetermined number of dark line portions DL31, such as every four dark line portions DL31, two specific dark line portions that are adjacent to each other remain in the exposure pattern PS31 as the dark line portions DL33.

FIG. 12(D) is a diagram showing a mask pattern that includes light-transmitting portions MBP32 and a light-shielding portion MDP32 formed in the third region MPA5 of the mask M1 by the exposure method of the third embodiment (substantially the same as the mask pattern formed in the third region MPA5 in FIG. 11). In the same manner as the exposure method of the second embodiment, when the plate P is exposed with the projection optical system PL1, for example, the light source LS4 included in the illumination optical module IM3 for illuminating the third region MPA5 repetitively starts and stops the emission of light in a time-sharing manner in cooperation with the relative scanning of the plate P. More specifically, a control mechanism (not shown) provides instructions to the light controller LC4 (not shown) while the plate P is being scanned and exposed to repetitively start and stop the emission of light from the light source LS4 whenever a predetermined time elapses or whenever a predetermined distance is exposed. As a result, the illumination optical module IM3 repetitively performs illumination and non-illumination of the third region MPA5 in the mask in a time-sharing manner. Consequently, the projection optical system PL1 repetitively performs illumination and non-illumination of the plate P with exposure light.

FIG. 12(E) shows one example of an exposure pattern PM32 formed on the plate P through the exposure described above. Discrete rectangular regions arranged under the light-transmitting portions MBP32 when the light source LS4 emits light become bright portions BL34. The remaining portions form a dark portion DL34. Each bright portion BL34 has a width W127 in the X direction that is substantially equal to the width W125 of each light-transmitting portion MBP32 in the X direction. A center interval YDP6 between the bright portions BL34 in the Y direction is determined by the time interval at which the light controller LC4 (not shown) repetitively stops the emission of light from the light source LS4 and by the scanning speed of the plate stage PS, which supports the plate P. Accordingly, the time interval at which the light source LS4 stops emitting light and the scanning speed of the plate stage PS may be controlled to control the center interval YDP6. Further, the duty ratio of the emission time and non-emission time of the light source LS4 can be controlled to control the Y direction width W128 of the dark portion DL34 between the bright portions BL34 in the Y direction.

An exposure pattern PS32, which is a composite pattern of the exposure pattern PS31 and the exposure pattern PM32 described above, will now be described with reference to FIG. 12 (F). In the third embodiment, portions that are bright in the exposure pattern formed on the plate P by illuminating any one of the first region IPA3, the second region MPA4, and the third region MPA5 with the illumination light become a bright portion BL35 in the exposure pattern PS32, which is a composite pattern. Accordingly, the dark portions in the exposure pattern PS32 are restricted to portions that are dark in both of the exposure pattern PS31 and the exposure pattern PM32. More specifically, in the exposure method of the third embodiment, in every predetermined number of dark line portions DL31, such as every four dark line portions DL31, two specific dark line portions that are adjacent to each other in the exposure pattern PI31 formed during the fine period exposure are selected, and specific regions of the selected dark line portions DL31 in the Y direction form dark line portions DL35 as the dark portions ultimately formed on the plate P.

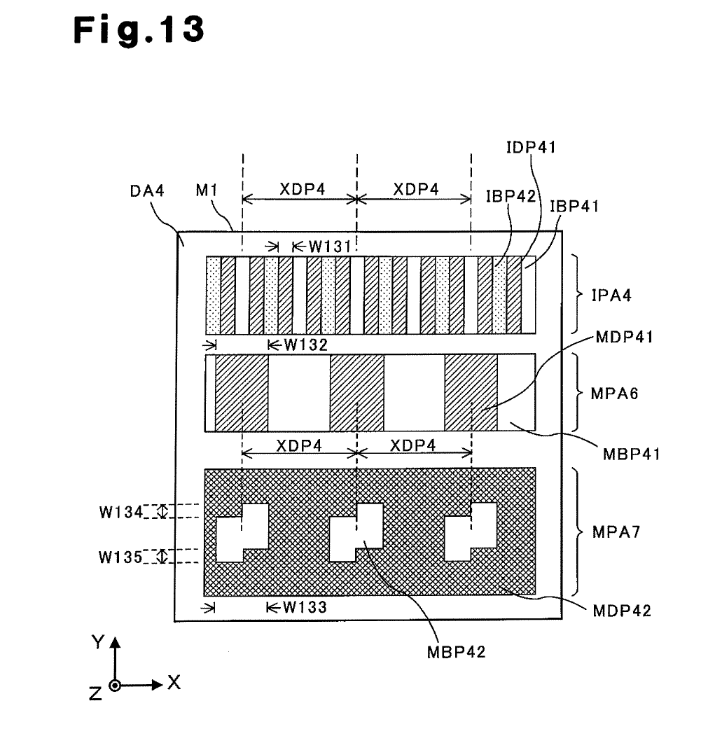

The structure of a mask applicable to the exposure method of the fourth embodiment will now be described. The mask is a modified example of the mask M1 shown in FIG. 11. FIG. 13 shows one example of the structure of the mask M1 on which part of a mask pattern of the fourth embodiment is formed. The mask M1 includes a first region IPA4 and a second region MPA6 that are substantially identical to the first and second regions in the mask M1 of the third embodiment shown in FIG. 11. Therefore, the first region IPA1 and the second region MPA6 will not be described. A mask pattern including light-transmitting portions MBP42 and a light-shielding portion MDP42 is formed in a third region MPA7 of the mask M1. The center interval between the light-transmitting regions MBP42 in the X direction is set to be the same as the center interval XDP4 between the light-shielding portions MDP41 of the second region MPA6. Each light-transmitting portion MBP42 has a width W133 in the X direction that is set to be substantially the same as the width W132 of each light-shielding portion MDP41 in the second region MPA6. The light-transmitting portions MBP42 are each shaped differently from the light-transmitting portions MBP32 of the third region MPA5 in FIG. 11. Each light-transmitting portion MBP42 has extensions in the +Y direction and in the −Y direction. One extension has a predetermined width W134 in the +Y direction, and the other extension has a predetermined width W135 in the −Y direction.

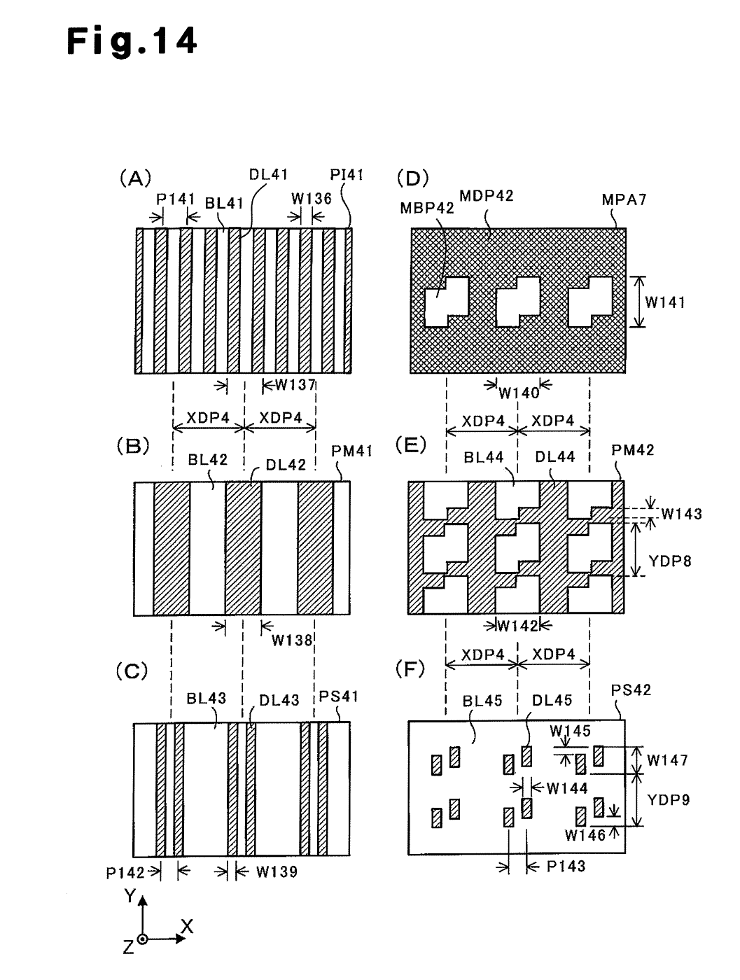

An exposure pattern that is formed on the plate P using the mask M1 shown in FIG. 13 will now be described in detail with reference to FIG. 14. The exposure pattern is basically the same as the exposure pattern shown in FIG. 12. The mask patterns formed in the first region IPA4 and the second region MPA6 shown in FIG. 13 are substantially the same as the mask patterns formed in the first region IPA3 and the second region MPA4 shown in FIG. 11. Thus, an exposure pattern PI41 shown in FIG. 14(A), an exposure pattern PM41 shown in FIG. 14(B), and an exposure pattern PS41 shown in FIG. 14(C) will not be described.

FIG. 14(D) is a diagram showing part of a mask pattern that includes light-transmitting portions MBP42 and light-shielding portions MDP42 formed in the third region MPA7 of the mask M1 (substantially the same as the mask pattern formed in the third region MPA7 shown in FIG. 13). In the same manner as the exposure method of the second embodiment, when the plate P is exposed with the projection optical system PL1, for example, the light source LS4 included in the illumination optical module IM3 for illuminating the third region MPA7 repetitively starts and stops the emission of light in a time-sharing manner in cooperation with the relative scanning of the plate P. More specifically, a control mechanism (not shown) provides instructions to the light controller LC4 (not shown) while the plate P is being scanned and exposed to repetitively start and stop the emission of light from the light source LS4 whenever a predetermined time elapses or whenever a predetermined distance is exposed. As a result, the illumination optical module IM3 repetitively performs illumination and non-illumination of the third region MPA7 in the mask in a time-sharing manner. Consequently, the projection optical system PL1 repetitively performs illumination and non-illumination of the plate P with exposure light.

FIG. 14(E) shows one example of an exposure pattern PM42 that is formed on the plate P through the exposure described above. Discrete rectangular regions arranged under the light-transmitting portions MBP42 when the light source LS4 emits light become bright portions BL44. The remaining portions form a dark portion DL44. Each bright portion BL44 has a width W142 in the X direction that is substantially equal to the width W140 of each light-transmitting portion MBP42 in the X direction. A center interval YDP8 between the bright portions BL44 in the Y direction is determined by the time interval at which the light controller LC4 repetitively stops the emission of light from the light source LS4 and by the scanning speed of the plate stage PS, which supports the plate P. Accordingly, the time interval at which the light source LS4 stops emitting light and the scanning speed of the plate stage PS may be controlled to control the center interval YDP8. Further, the duty ratio of the emission time and non-emission time of the light source LS4 can be controlled to control the Y direction width W143 of the dark portion DL44 between the bright portions BL44 in the Y direction.

An exposure pattern PS42, which is a composite pattern of the exposure pattern PS41 and the exposure pattern PM42 described above, will now be described with reference to FIG. 14(F). In the fourth embodiment, portions that are bright in the exposure pattern formed on the plate P by illuminating any one of the first region IPA4, the second region MPA6, and the third region MPA7 with the illumination light become a bright portion BL45 in the exposure pattern PS42, which is a composite pattern. Accordingly, the dark portions in the exposure pattern PS42 are restricted to portions that are dark in both of the exposure pattern PS41 and the exposure pattern PM42. More specifically, in the exposure method of the fourth embodiment, in every predetermined number of dark line portions DL41, such as every four dark line portions DL41, two specific dark line portions that are adjacent to each other in the exposure pattern PI41 formed during the fine period exposure are selected, and specific regions of the selected dark line portions DL41 in the Y direction form dark line portions DL45 as the dark portions ultimately formed on the plate P. Further, two adjacent dark line portions DL45 are offset from each other by a predetermined width (W145 or W146) in the Y direction.

With the exposure methods of the third and fourth embodiments described above, finer patterns are formed with high accuracy through the fine period exposure and the middle density exposure. Further, desirable ones of the adjacent patterns are selected and restricted to specific regions in the Y direction.

In each of the above embodiments, the mask patterns and the exposure patterns shown in the drawings are parts of the mask M1 or the like and the partial region E1 or the like. Accordingly, in the exposure methods of each of the above embodiments, it is apparent that many exposure patterns can be formed on the entire surface of the partial region E1 or the like. It is also apparent that the employment of the masks M1 to M7 enables the formation of many exposure patterns on substantially the entire surface of the plate P. Further, the masks used in the exposure methods of the above embodiments are mere examples of masks that are applicable to the exposure apparatus of the embodiment. The structures of the masks M1 to M7 are not limited to the examples shown in the drawings.

In each of the above embodiments, the light sources LS1 to LS3 of the illumination optical systems constantly emit light during scanning exposure. However, the light sources LS1 to LS3 may repetitively start and stop the emission of light during scanning exposure depending on the shape of the exposure pattern that is to be formed on the plate P in the same manner as the light source LS4 of the illumination optical system.

It is apparent that the exposure method in each of the above embodiments may be performed in combination with positive photoresist or negative photoresist.

Further, the exposure apparatus of the embodiment includes the plurality of projection optical systems PL1 to PL7 respectively exposing the partial regions E1 to E1 into which the entire surface of the plate P is divided. Accordingly, is preferable that each of the projection optical systems PL1 to PL7 includes, in the X direction, an exposure field covering the corresponding one of the partial regions E1 to E7, and that the exposure field has a rectangular shape defined by two sets of sides that are parallel to the X direction and the Y direction. However, the exposure apparatus of the embodiment may include overlapping regions V1 to V6 arranged between the partial regions E1 to E7 of the plate P. As described above, for example, the overlapping region V1 shown in FIG. 3 is exposed in an overlapped manner with the two projection optical systems PL1 and PL5 corresponding to the two partial regions E1 and ES. When such overlapping regions V1 to V6 are formed, it is preferable that the exposure field of each of the projection optical systems PL1 to PL7 has a trapezoidal shape having two sides parallel to the X direction.

In the embodiment, the optical unit OU1 is described as one example, and the optical units OU2 to OU7, which are the same as the optical unit OU1, are not described.

The exposure apparatus of the embodiment may form a new pattern on a plate pattern that has been formed on the plate P in a previous process. In this case, the exposure apparatus maintains a predetermined positional relationship with the plate pattern when forming the new pattern. In such an exposure, the exposure apparatus of the embodiment includes position detection optical systems ALR1 and ALR2 as shown in FIG. 1. Before the exposure described in each of the above embodiments is performed, the position detection optical systems ALR1 and ALR2 detect the position of the existing plate pattern on the plate P. Based on the detected position information, the exposure apparatus exposes a new exposure pattern on the plate P while maintaining the predetermined positional relationship with the existing plate pattern. Further, the scanning exposure in each of the above embodiments may be performed while detecting the position of the plate pattern formed on the plate P. In this case, the position information of the plate pattern detected by the position detection optical systems ALR1 and ALR2 is sent to a position control system (not shown). The position control system calculates a target control position of the plate stage PS based on the position information and sends a control signal to the linear motor system, which is formed by the movable elements LM1 and LM2 and the fixed elements LG1 and LG2 arranged on the base plate BP, to control the position of the plate stage PS.

Further, based on the Y direction position of the plate pattern on the plate P detected by the position detection optical systems ALR1 and ALR2, the light controller, such as the illumination optical system IL1 or the like, may be controlled to control light emission from the light source. More specifically, exposure may be performed on the third region MPA3 or the like of the mask M1 when the third region MPA3 or the like satisfies a predetermined relationship with a predetermined plate pattern, while otherwise stopping the exposure of the third region MPA3 or the like.

The mask of the embodiment may be a mask that is significantly smaller than the plate that is exposed. The mask may have any size that is available and easily allows for high accuracy. For example, the mask may be sized to have a pattern region in which one side is 100 mm or less so that it can be accommodated in a 150×150 mm mask plate that is typically used in a lithography process for manufacturing an LSI (large-scale integrated) circuit.

The mask of the embodiment is a light-transmitting mask but may be a reflective mask instead. As a reflective mask, a mask formed by a movable micro-mirror array (such as a variably shaped mask) may be used.

In the mask of the embodiment, the fine period mask pattern is formed in the first region and the middle density mask pattern is formed in the second region of the mask. However, it is obvious that the middle density mask pattern may be formed in the first region of the mask and the fine period mask pattern may be formed in the second region of the mask.

In the embodiment, the illumination light that illuminates the first region, the second region, and the third region of the mask may have different illumination conditions (e.g., a coherence factor (emission-side numerical aperture of the illumination optical system/incident-side numerical aperture of the projection optical system) or deformed illumination). More specifically, an illumination optical system may illuminate the first region with illumination light having a small coherence factor (e.g., illumination light with an incident angle range of ±1° or less) and the second or third region with illumination light having a normal coherence factor.

Further, an illumination optical system may illuminate the first, second, and third regions with illumination light having a small coherence factor only in the periodic direction of the mask pattern (or in a predetermined direction) and a large coherence factor in a direction orthogonal to the periodic direction of the mask pattern. Such an illumination system is described, for example, in International Patent Publication No. WO 2006/075720 (in particular, FIGS. 6, 7, 8, and 9).

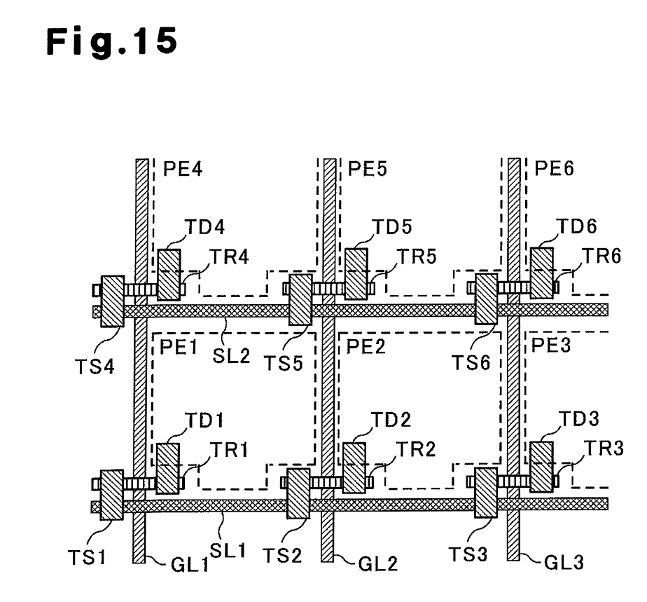

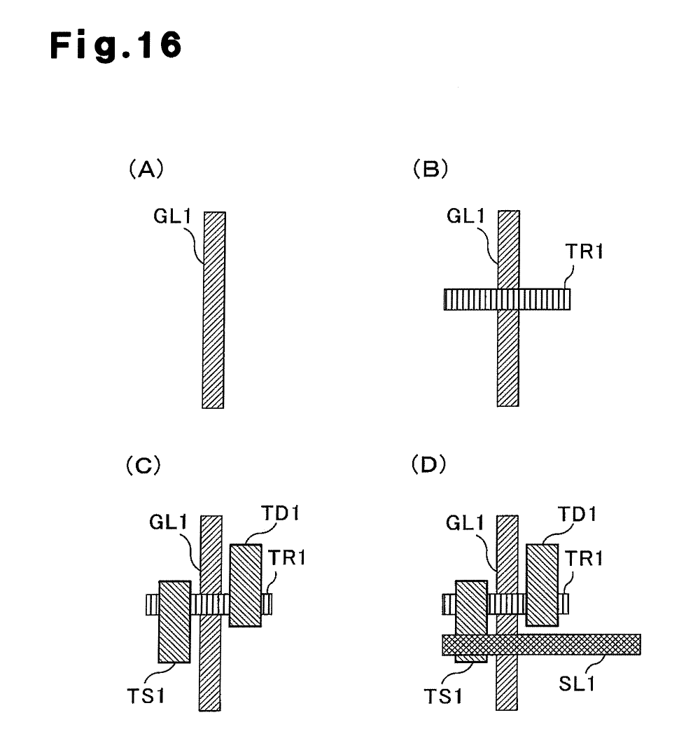

One example of a method for manufacturing a plate for a flat panel display using the exposure apparatus and exposure method of the embodiment will now be described with reference to FIGS. 15 and 16. FIG. 15 is an enlarged view showing a display pixel unit (e.g., a TFT transistor unit) formed on a glass plate that functions as a liquid crystal display, which is one example of the flat panel display. Among a plurality of display pixels shown in FIG. 15, a display pixel including a transparent electrode PE1, an active area TR1 that forms a transistor, a source electrode TS1, and a drain electrode TD1 will now be described. A signal line SL1 for transmitting a display signal and a selection line GL1 for selecting the display pixel are connected to the display pixel.

The display pixel unit is manufactured in the embodiment by performing each of the processes described below. In the first process, a selection line GL1 is formed on a glass plate as shown in FIG. 16(A). As shown in FIG. 15, the selection line GL1 is a linear pattern extending in one direction and is part of the plurality of plate patterns GL1, GL2, and GL3, which are arranged at a relatively large period in a direction orthogonal to the direction in which the patterns extend. Thus, the selection line GL1 can be formed with the exposure method of the first embodiment shown in FIG. 7. Accordingly, a metal thin film of aluminum or tantalum etc., which is the material for the selection line GL, is formed on the glass plate, and positive photoresist is applied to the metal thin film. Further, the exposure of the first embodiment is performed, and the photoresist is then developed. The metal thin film is then etched using the resist pattern as an etching mask. This forms the selection lines GL1, GL2, and GL3.

In the second process, a plate pattern that includes the active area TR1, which forms a thin-film transistor, is formed so as to intersect the selection line GL1 as shown in FIG. 16(B). The active area TR1 is a linear pattern having a predetermined length. The active area TR1 is part of plate patterns TR1, TR2, TR3, TR4, TR5, and TR6, which are periodically arranged in a two-dimensional manner in accordance with the layout period of the display pixels. Thus, the active area TR1 may be formed by performing exposure as in the exposure method of the second embodiment shown in FIG. 10. Accordingly, a semiconductor thin film of amorphous silicon or polysilicon etc., which is the material for the active area TR1, is formed on a glass plate. Positive photoresist is applied to the semiconductor thin film, and exposure of the second embodiment is performed. The photoresist is then developed. The semiconductor thin film is etched using the obtained resist pattern as an etching mask. This forms the active area TR1. During the exposure, from the state in which the selection line GL1 is exposed, the glass plate must be rotated by 90 degrees for mounting on the exposure apparatus of the embodiment. This is because of the 90 degree difference between the longitudinal directions of the plate patterns for the selection line GL and the active area TR1.

In the third process, the source electrode TS1 and the drain electrode TD1, which serve as electrodes for a thin-film transistor, are formed on the two ends of the active area TR1 as shown in FIG. 16(C). The source electrode TS1 and the drain electrode TD1 are two linear patterns having predetermined lengths in a direction parallel to the selection line GL1. The source electrode TS1 and the drain electrode TD1 are arranged adjacent to each other but offset from each other by a predetermined length in a direction parallel to the selection line GL1. The pair of these two linear patterns are part of the plate patterns TS1, TD1, TS2, TD2, TS3, TD3, TS4, TD4, TS5, TD5, TS6, and TD6, which are periodically arranged in a two-dimensional manner in accordance with the layout period of the display pixels. Thus, the source electrode TS1 and the drain electrode TD1 can be formed by performing the exposure according to the exposure method of the third embodiment shown in FIGS. 11 to 14 (in particular the fourth embodiment shown in FIGS. 13 and 14). Accordingly, a metal thin film of aluminum or the like, which is the material for the source electrode TS1 and the drain electrode TD1, and a semiconductor thin film of amorphous silicon or the like are formed on the glass plate. Positive photoresist is applied to the metal thin film or the semiconductor thin film. Exposure is then performed in accordance with the third embodiment. The photoresist is then developed. The thin film is then etched using the obtained resist pattern as an etching mask. This forms the source electrode TS1 and the drain electrode TD1.

In the fourth process, the signal line SL1 is formed at a position aligned with the source electrode as shown in FIG. 16(D). The signal line SL1 is a linear pattern extending in a direction orthogonal to the selection line GL1. The signal line SL1 is part of the plate patterns SL1 and SL2, which are periodically arranged in a one-dimensional manner in accordance with the layout period of the display pixels. Thus, the signal line SL1 can be formed by performing exposure according to the first embodiment of the exposure method shown in FIG. 7. Accordingly, a metal thin film aluminum or the like, which is a material for the signal line SL1, or a semiconductor thin film of amorphous or the like is formed on the glass plate. Positive photoresist is applied to the metal thin film or semiconductor thin film. Exposure is then performed in accordance with the first embodiment. Further, the photoresist is developed, and the thin film is etched using the obtained resist pattern as an etching mask. This forms the signal line SL1. During the exposure, from the state in which the selection line GL1 is exposed, the glass plate must be rotated by 90 degrees for mounting on the exposure apparatus of the embodiment. This is because of the 90 degree difference between the longitudinal directions of the plate patterns for the selection line GL and the signal line SL1.

In the fifth process, the transparent electrodes PE1, PE2, PE3, PE4, PE5, and PE6 are each formed so that they are partially aligned with the corresponding drain electrodes. The transparent electrodes PE1 to PE6 each have a width that is not as fine as other elements, such as the source electrode and drain electrode. Thus, the transparent electrodes PE1 to PE6 can be formed using a conventional proximity exposure method or a conventional projection exposure method instead of using the exposure methods according to the embodiments of the present invention.

This completes the manufacturing of the display pixel unit on the plate used in the liquid crystal display. If the plate pattern is not that fine, in each of the first to fifth processes, exposure may be performed by employing a conventional proximity exposure method or a projection exposure method instead of employing the exposure method of each of the above the embodiments. Further, a plate for a flat panel display may be manufactured by combining various types of known techniques with the manufacturing method for the display pixel unit described above.

The manufacturing method of the flat panel display described above is not limited to the above embodiments. Any exposure pattern may be formed using the exposure method of one of the above embodiments in at least one of the processes for manufacturing the plate described above.

In the above embodiments, the term adjacent does not necessarily mean that the fine period mask pattern region and the middle density mask pattern region of the mask are in contact with each other and may mean that they are spaced apart by a predetermined distance, as shown in FIG. 2. In the embodiment, it is preferable that the fine period mask pattern region and middle density mask pattern region of the mask be spaced apart from each other by a distance within a range that is greater than or equal to the width of the fine period mask pattern region in the Y direction and less than or equal to five times the width of the fine period mask pattern region in the Y direction.

The invention is not limited to the foregoing embodiments but various changes and modifications of its components may be made without departing from the scope of the present invention. Also, the components disclosed in the embodiments may be assembled in any combination for embodying the present invention. For example, some of the components may be omitted from all the components disclosed in the embodiments. Further, components in different embodiments may be appropriately combined.

What is claimed is:

1. An exposure method for exposing a plate by illuminating a mask with illumination light and using a mask pattern on the mask, the method comprising:
scanning the plate relative to the mask in a scanning direction, which is an in-plane direction of the plate; and
exposing the plate during the relative scanning, wherein the exposing includes performing both a fine period exposure, which uses a fine period mask pattern formed in a first region of the mask, and a middle density exposure, which uses a middle density mask pattern formed in a second region of the mask, the first region and the second region being adjacent to each other in the scanning direction.

2. The exposure method according to claim 1, wherein the fine period mask pattern includes a phase member for producing a predetermined phase difference in part of the fine period mask pattern.

3. The exposure method according to claim 2, wherein the phase member produces a phase difference of substantially (2n+1)π[rad] (where n is an integer) for the illumination light.

4. The exposure method according to claim 1, wherein the middle density pattern is formed in accordance with the fine period mask pattern.

5. The exposure method according to claim 1, wherein the middle density exposure includes forming a plurality of beam spots on the plate with the middle intensity mask pattern.

6. The exposure method according to claim 1, wherein the exposing the plate during the relative scanning includes performing the fine period exposure and the middle density exposure so as to align a specific dark line portion of an exposure pattern formed on the plate by the fine period exposure with a specific dark line portion of an exposure pattern formed on the plate by the middle density exposure.

7. The exposure method according to claim 1, wherein:
the fine period exposure includes exposing an exposure pattern having a plurality of dark line portions and a plurality of bright line portions on the plate; and
the middle density exposure includes exposure that leaves as a dark line portion at least one specific dark line portion, which is among the plurality of dark line portions formed on the plate by the fine period exposure, and changes each of the other dark line portions to a bright portion.

8. The exposure method according to claim 1, wherein:
the fine period exposure includes exposing an exposure pattern having a plurality of dark line portions and a plurality of bright line portions on the plate; and
the middle density exposure includes exposure that leaves as a dark line portion a specific region defined at a predetermined position in the scanning direction of at least one specific dark line portion, which is among the plurality of dark line portions formed on the plate by the fine period exposure.

9. The exposure method according to claim 1, wherein:
the fine period exposure includes exposing an exposure pattern having a plurality of dark line portions and a plurality of bright line portions on the plate; and
the middle density exposure includes exposure that leaves as a dark line portion a specific region defined at a predetermined position in the scanning direction of at least two adjacently arranged specific dark line portions, which are among the plurality of dark line portions formed on the plate by the fine period exposure.

10. The exposure method according to claim 1, wherein the middle density exposure includes performing exposure by switching between states of emission and non-emission of exposure light to the plate in a time-sharing manner.

11. The exposure method according to claim 1, wherein:
the scanning the plate relative to the mask includes scanning the plate relative to a plurality of masks, each of which is the mask, in a scanning direction, which is an in-plane direction of the plate; and
the exposing the plate during the relative scanning includes performing the fine period exposure and the middle density exposure so as to expose the plate with mask patterns of the plurality of masks arranged in a zigzag along a non-scanning direction that is substantially orthogonal to the scanning direction.

12. The exposure method according to claim 1, wherein the mask includes a side having a length of 150 mm or less.

13. The exposure method according to claim 1, wherein:
the exposing the plate during the relative scanning includes performing the fine period exposure and the middle density exposure with illumination light of different illumination conditions.

14. The exposure method according to claim 1, further comprising:
detecting position information of a plate pattern on the plate during the relative scanning; and
controlling positional relationship of the mask and the plate based on the position information.

15. A method for manufacturing a plate for a flat panel display, the method comprising:
an exposure step, wherein at least part of the exposure step is performed by using the exposure method according to claim 1.

16. A method for manufacturing a plate for a flat panel display, the method comprising:
forming a thin film transistor; and
forming a source electrode and a drain electrode of the thin film transistor by using the exposure method according to claim 9.

17. An exposure apparatus for exposing a pattern on a plate, the exposure apparatus comprising:
an optical unit including an illumination optical system and a projection optical system;
a movable mechanism which scans the plate relative to the optical unit in a scanning direction, which is an in-plane direction of the plate; and
a mask holding mechanism which is capable of holding a mask on a first plane defined by the optical unit;
wherein the illumination optical system illuminates with illumination light a first region and a second region adjacently arranged in the scanning direction on the first plane; and
the projection optical system projects at least part of a region on the first plane that includes the first region and the second region.

18. The exposure apparatus according to claim 17, wherein the optical unit is one of a plurality of optical units.

19. The exposure apparatus according to claim 18, wherein the plurality of optical units are arranged in a zigzag along a non-scanning direction that is substantially orthogonal to the scanning direction.

20. The exposure apparatus according to claim 18, wherein the plurality of optical units form an exposure region including an overlapping region on the plate.

21. The exposure apparatus according to claim 17, wherein the illumination optical system includes a switching mechanism capable of switching between states of emission and non-emission of the illumination light to at least one of the first region and the second region in a time-sharing manner.

22. The exposure apparatus according to claim 17, further comprising:
a switching mechanism arranged in an optical path of exposure light for exposing the plate, wherein the switching mechanism is capable of switching between states of emission and non-emission of the exposure light to at least one of the first region and the second region in a time-sharing manner.

23. The exposure apparatus according to claim 17, further comprising:
an illumination changing mechanism capable of changing an illumination condition of at least one of illumination light that illuminates the first region and illumination light that illuminates the second region.

24. The exposure apparatus according to claim 17, wherein the illumination optical system includes a first illumination optical module that illuminates the first region and a second illumination optical module that illuminates the second region.

25. The exposure apparatus according to claim 17, wherein the illumination optical system illuminates at least one of the first region and the second region with illumination light having an incident angle range of ±1° or less in at least one direction.

26. The exposure apparatus according to claim 17, wherein the illumination optical system illuminates with illumination light a third region arranged on the first plane adjacent to the first region or the second region in the scanning direction.

27. The exposure apparatus according to claim 17, further comprising:
a position detection unit which detects position information of a plate pattern on the plate during the relative scanning; and
a control unit which controls positional relationship of the projection optical system and the plate based on the position information detected by the position detection unit.

28. The exposure apparatus according to claim 27, further comprising:
a switching mechanism which is capable of switching between states of emission and non-emission of the illumination light or exposure light to at least one of the first region and the second region based on the detected position information.

29. The exposure apparatus according to claim 17, wherein the mask arranged on the first plane includes a fine period mask pattern formed in the first region and a middle density mask pattern formed in the second region.

30. The exposure apparatus according to claim 17, wherein the mask is a variably shaped mask.

31. The exposure apparatus according to claim 17, further comprising:
an exchanging mechanism enabling the mask arranged on the first plane to be exchanged.
